(19) United States
(12) Patent Application Publication
(10) Pub. No.: US 2017/0291846 A1
(43) Pub. Date: Oct. 12, 2017

(54) HALOGENIDE CONTAINING GLASSES IN METALLIZATION PASTES FOR SILICON SOLAR CELLS

(71) Applicant: Heraeus Precious Metals North America Conshohocken LLC, West Conshohocken, PA (US)

(72) Inventors: Gerd SCHULZ, Conshohocken, PA (US); Ryan MAYBERRY, Turnersville, NJ (US); Daniel Winfried HOLZMANN, Blue Bell, PA (US); Christian JUNG, Oberhaid (DE); Matthias HORTEIS, Bryn Mawr, PA (US); Gregory BERUBE, Nashua, NH (US)

(21) Appl. No.: 15/093,328

(22) Filed: Apr. 7, 2016

(51) Int. Cl. C03C 8/18; H01L 31/0216; H01L 31/068; H01L 31/0224; H01L 31/18

(52) U.S. Cl. CPC C03C 8/18; H01L 31/022441; H01L 31/1864; H01L 31/0682; H01L 31/02167

(57) ABSTRACT

In general, the invention relates to a paste comprising:

i) silver particles;
ii) a particulate lead-silicate glass comprising
iia) at least one oxide of silicon;
iib) at least one oxide of lead;
iic) at least one chloride;
iid) optionally at least one further oxide being different from components iia) and iib);
   iii) an organic vehicle.

The invention also relates to a solar cell precursor, to a process for the preparation of a solar cell, to a solar cell obtainable by this process, to a module comprising such a solar cell and to the use of a particulate lead-silicate glass as a component in a silver paste that can be used for the formation of an electrode.

### FIELD OF THE INVENTION

In general, the present invention relates to a paste, to a solar cell precursor, to a process for the preparation of a solar cell, to a solar cell obtainable by this process, to a module comprising such a solar cell and to the use of a particulate lead-silicate glass as a component in a silver paste that can be used for the formation of an electrode.

### BACKGROUND OF THE INVENTION

Solar cells are devices that convert the energy of light into electricity using the photovoltaic effect. Solar power is an attractive green energy source because it is sustainable and produces only non-polluting by-products. Accordingly, a great deal of research is currently being devoted to developing solar cells with enhanced efficiency while continuously lowering material and manufacturing costs. When light hits a solar cell, a fraction of the incident light is reflected by the surface and the remainder transmitted into the solar cell. The transmitted photons are absorbed by the solar cell, which is usually made of a semiconducting material, such as silicon which is often doped appropriately. The absorbed photon energy excites electrons of the semiconducting material, generating electron-hole pairs. These electron-hole pairs are then separated by p-n junctions and collected by conductive electrodes on the solar cell surfaces. FIG. 1 shows a minimal construction for a simple solar cell.

Solar cells are very commonly based on silicon, often in the form of a Si wafer. Here, a p-n junction is commonly prepared either by providing an n-type doped Si substrate and applying a p-type doped layer to one face or by providing a p-type doped Si substrate and applying an n-type doped layer to one face to give in both cases a so called p-n junction. The face with the applied layer of dopant generally acts as the front face of the cell, the opposite side of the Si with the original dopant acting as the back face. Both n-type and p-type solar cells are possible and have been exploited industrially. Cells designed to harness light incident on both faces are also possible, but their use has been less extensively harnessed.

In order to allow incident light on the front face of the solar cell to enter and be absorbed, the front electrode is commonly arranged in two sets of perpendicular lines known as “fingers” and “bus bars” respectively. The fingers form an electrical contact with the front face and bus bars link these fingers to allow charge to be drawn off effectively to the external circuit. It is common for this arrangement of fingers and bus bars to be applied in the form of a metallization paste which is fired to give solid electrode bodies. A back electrode is also often applied in the form of a metallization paste which is then fired to give a solid electrode body.

Currently commercially available metallization pastes for silicon solar cells consist of silver powders, an organic vehicle and either a lead-tellurium glass or a lead-silicate glass combined with a metal oxide additive that enables the formation of an electric contact between Si wafer and the solid electrode body. These pastes are limited in terms of the optimum firing temperature and the doping level of the Si wafer. The optimum temperature for firing is about 800° C. and the sheet resistance of the Si wafer should not exceed 130 Ω/sq in order to achieve a low contact resistance.

Due to the limitations of currently available frontside pastes all other components of the solar cell (like Al pastes or passivation layers) were developed to match these requirements. For instance the manufacturing of n-type cells is not designed to achieve the highest possible efficiency but to match the requirements of all different pastes and layers used in the process in order to enable a good contact formation. There is always a trade-off between efficiency and process required firing temperature. Therefore metallization pastes able to contact the Si wafer at lower firing temperatures would have the potential to increase cell efficiency—especially for new cell concepts like n-type or PERC (PERC=“passivated emitter rear cell”).

WO 2013/105812 A1 discloses a glass frit that comprises SiO₂, PbO, and at least one oxide selected from the group consisting of Al₂O₃, ZrO₂, ZnO, and Li₂O and the use of this glass frit as a component in a conductive silver paste. In the examples of this prior art document the silver paste, after it has been applied onto a Si wafer, is fired at a temperature in the range from 600 to 900° C. in order to produce a front surface electrode. However, the temperature that is requited to fire the silver pastes disclosed in WO 2013/105812 A1 is still too high to enable the production of a solar cell with a sufficient efficiency. Furthermore, the back surface of the Si wafer is coated with an aluminum paste for the formation of the back electrode and this aluminium paste has to be fired at a temperature of about 800° C. The silver paste used for the front surface electrode and the aluminium paste used for the back electrode therefore do not match in the temperatures that are required for firing these pastes.

### SUMMARY OF THE INVENTION

The invention is generally based on the object of overcoming at least one of the problems encountered in the state of the art in relation to solar cells.

More specifically, the invention is based on the object of providing solar cells with improved electrical properties such as favourable cell efficiency η and series resistance Rₛₑᵣ, particularly in both, standard BSF cells (BSF=“back surface field”) and new cell concepts like PERC or n-type solar cells.

Furthermore, it was an object of the present invention to provide a silver paste that can be used to form electrodes in an n-type solar cell, wherein this paste can be applied on the front and/or the back side of an n-type Si wafer, allowing the replacement of the currently used combination of Al-containing and standard frontside pastes that do not match in optimum firing temperature. Moreover, the silver paste should allow the formation of electrodes on the surface of a Si wafer with lower firing temperatures compared to corresponding silver pastes known from the prior art.

It was also an object of the present invention to provide a silver paste that can be used to form electrodes in a p-type solar cell, wherein this paste can be applied on the front side of a p-type Si wafer and can subsequently be fired at a lower firing temperature compared to corresponding silver pastes known from the prior art.

A contribution to achieving at least one of the above described objects is made by the subject matter of the category forming claims of the invention. A further contribution is made by the subject matter of the dependent claims of the invention which represent specific embodiments of the invention.

### EMBODIMENTS

   |1| A paste comprising:
   i) silver particles;
   ii) a particulate lead-silicate glass comprising,
      iia) at least one oxide of silicon;
      iib) at least one oxide of lead;
      iic) at least one chloride;
      iid) optionally at least one further oxide being different from components iia) and iib);
   iii) an organic vehicle.
   |2| The paste according to embodiment |1|, wherein the silver particles i) have a d₅₀-value in a range from 0.1 to 10 μm, more preferably in a range from about 1 to about 10 μm and most preferably in a range from about 1 to about 5 μm.
   |3| The paste according to embodiment |1|, wherein the silver particles i) have a d₅₀-value in a range from about 0.5 to about 4 μm, preferably in a range from about 1 to about 3.5 μm, more preferably in a range from about 1 to about 2 μm.
   |4| The paste according to anyone of the preceding embodiments, wherein the silver particles i) are present with a surface coating.
   |5| The paste according to embodiment |4|, wherein the coating corresponds no more than about 8 wt %, preferably no more than about 5 wt %, most preferably no more than about 1 wt %, in each case based on the total weight of the silver particles.
   |6| The paste according to anyone of the preceding embodiments, wherein the oxide of silicon iia) is SiO₂.
   |7| The paste according to anyone of the preceding embodiments, wherein the oxide of lead iib) is selected from the group consisting of PbO, PbO₂, Pb₃O₄ and a mixture of at least two of these oxides.
   |8| The paste according to anyone of the preceding embodiments, wherein the at least one chloride iic) is selected from the group consisting of MnCl₂, ZnCl₂, AgCl, PbCl₂, CrCl₂, CrCl₃, FeCl₂, FeCl₃, CoCl₂, NiCl₂, CuCl, CuCl₂, LiCl, NaCl, KCl, RbCl, CsCl, MgCl₂, CaCl₂, SrCl₂, BaCl₂, SnCl₂, LaCl₃ and a mixture of at least two of these chlorides.
   |9| The paste according to embodiment |8|, wherein the at least one chloride iic) is selected from the group consisting of LiCl, NaCl, KCl, MgCl₂, CaCl₂, SrCl₂, BaCl₂, ZnCl₂, PbCl₂, AgCl, CrCl₃, MnCl₂, LaCl₃, and a mixtures of at least two of these chlorides.
   |10| The paste according to anyone of the preceding embodiments, wherein the at least one further oxide iid) being different from components iia) and iib) is an oxide selected from the group consisting of the oxides of aluminium, boron, phosphorus, titanium, zirconium, cerium, lanthanum, vanadium, niobium, tantalum, chromium, molybdenum, tungsten, manganese, iron, cobalt, nickel, copper, zinc, silver, lithium, sodium, potassium, rubidium, caesium, magnesium, calcium, strontium, barium, tin, bismuth, or a mixture of at least two, at least three or at least four of these oxide.
   |11| The paste according to embodiment |10|, wherein the at least one further oxide iid) being different from components iia) and iib) is selected from the group consisting of B₂O₃, Li₂O, P₂O₅, ZrO₂, TiO₂, V₂O₅, Ta₂O₅, Nb₂O₅, MoO₃, WO₃, MnO, ZnO, Bi₂O₃, MgO, SrO, BaO and a mixture of at least two, at least three or at least four of these oxides.
   |12| The paste according to anyone of the preceding embodiments, wherein the particulate lead-silicate glass ii) comprises
   iia) at least 5 mol %, preferably at least 10 mol % and more preferably at least 15 mol % of the at least one oxide of silicon, preferably SiO₂;
   iib) 25 to 80 mol %, preferably 30 to 75 mol % and more preferably 35 to 70 mol % of the at least one oxide of lead, preferably PbO, PbO₂, Pb₃O₄ or a mixture of at least two of these oxides;
   iic) 0.1 to 50 mol %, preferably 1 to 25 mol % and more preferably 2 to 10 mol % of at least one chloride;
   iid) 1 to 40 mol %, more preferably 3 to 30 mol % and more preferably 5 to 20 mol % of at least one further oxide being different from components iia) and iib);
   wherein the amounts are in each case based on the total mole number of components iia) to iid) in the glass and sum up to 100 mol %.
   |13| The paste according to anyone of the preceding embodiments, wherein the molar ratio of chloride ions to oxygen ions (Cl⁻:O²⁻) in the particulate lead-silicate is in the range from 0.001 to 1.5, preferably in the range from 0.01 to 0.5 and even more preferably in the range from 0.01 to 0.05.
   |14| The paste according to anyone of the preceding embodiments, wherein the particulate lead-silicate glass ii) is obtainable by mixing components iia), iib), iic) and optionally iid), melting the thus obtained mixture, cooling the thus obtained glass and subjecting it to pulverization.
   |15| The paste according to anyone of the preceding embodiments, wherein the particulate lead-silicate glass ii) comprises less than 0.1 mol %, more preferably less than 0.01 mol % and even more preferably less than 0.001 mol % of elemental silver, based on the total mole number of the components.
   |16| The paste according to anyone of the preceding embodiments, wherein the particulate lead-silicate glass has d₅₀-value in the range from 0.1 to 15 μm, more preferably in a range from about 0.2 to about 7 μm and most preferably in a range from about 0.5 to about 5 μm.
   |17| The paste according to anyone of the preceding embodiments, wherein the organic vehicles iii) comprises as vehicle components:
   (iiia) a binder, preferably in a range from about 1 to about 10 wt. %, more preferably in a range from about 2 to about 8 wt. % and most preferably in a range from about 3 to about 7 wt. %;
   (iiib) a surfactant, preferably in a range from about 0 to about 10 wt. %, more preferably in a range from about 0 to about 8 wt. % and most preferably in a range from about 0.01 to about 6 wt. %;
   (iiic) one or more solvents, the proportion of which is determined by the proportions of the other constituents in the organic vehicle;
   (iiic) optional additives, preferably in range from about 0 to about 10 wt. %, more preferably in a range from about 0 to about 8 wt. % and most preferably in a range from about 1 to about 5 wt. %;
   wherein the wt. % are each based on the total weight of the organic vehicle and add up to 100 wt. %.
   |18| The paste according to anyone of the preceding embodiments, comprising
   i) at least 60 wt.-%, preferably at least 70 wt.-% and more preferably at least 80 wt.-% of the silver particles;
   ii) 0.5 to 10 wt.-%, preferably 0.75 to 8 wt.-% and more preferably 1 to 5 wt.-% of the particulate lead-silicate glass;
   iii) 5 to 25 wt.-%, preferably 6 to 20 wt.-% and more preferably 7 to 15 wt.-% of the organic vehicle;
   iv) up to 10 wt.-%, preferably up to 5 wt.-% and more preferably up to 2.5 wt.-% of further additives being different from components i) to iii);
   wherein the amounts are in each case based on the total weight of the paste and sum up to 100 wt.-%.
   |19| The paste according to anyone of the preceding embodiments, wherein the viscosity of the paste is in the range of 5 to 75 Pas, preferably in the range from 5 to about 35 Pas, more preferably in a range from about 10 to about 25 Pas and most preferably in a range from about 15 to about 20 Pas.
   |20| A solar cell precursor comprising the following solar cell precursor constituents:
   a) a wafer having a front side and a back side;
   b) a paste according to anyone of embodiments |1| to |19| superimposed on at least one side of the wafer, the at least one side being selected from the group consisting of the front side and the back side.
   |21| The solar cell precursor according to embodiment |20|, wherein the wafer comprises a single body made up of a doped layer at the front side and a doped layer at the back side.
   |22| The solar cell precursor according to embodiment |20| or |21|, wherein the wafer is a Si wafer and wherein the thickness of the Si wafer is below about 0.5 mm, more preferably below about 0.3 mm and most preferably below about 0.2 mm.
   |23| The solar cell precursor according to anyone of embodiments |20| to |22|, wherein the wafer is an n-type doped Si wafer and wherein the paste is superimposed on both sides of the wafer.
   |24| The solar cell precursor according to anyone of embodiments |20| to |23|, wherein the wafer is a p-type doped Si wafer and wherein the paste is superimposed on the front side of the wafer.
   |25| A process for the preparation of a solar cell comprising the following preparation steps:
   A) provision of a solar cell precursor according to one of embodiments |20| to |24|;
   B) firing of the solar cell precursor to obtain a solar cell.
   |26| The process according to embodiment |25|, wherein the holding temperature in process step B) is a range from 660 to 760° C., preferably in a range from about 680 to about 740° C.
   |27| A solar cell obtainable by the process according to embodiment |25| or |26|.
   |28| The solar cell according to embodiment |27|, wherein the solar cell is an amorphous silicon cell, a monocrystalline cell, a multicrystalline cell, an amorphous silicon-polycrystalline silicon tandem cell, a silicon-silicon/germanium tandem cell, a string ribbon cell, a EFG (edge-defined film-fed-grown) cell, a PESC (passivated emitter solar cell), a PERC (passivated emitter, rear cell), a PERL (passivated emitter, rear locally diffused) cell or a standard BSF cell.
   |29| A module comprising at least two solar cells, at least one of which is a solar cell according to embodiment |27| or |28|.
   |30| Use of a particulate lead-silicate glass as defined in anyone of embodiment |1| and |6| to |16| as a component in a silver paste that can be used for the formation of an electrode.

### DETAILED DESCRIPTION

A contribution to achieving at least one of the above described objects is made by a paste comprising:
i) silver particles;
ii) a particulate lead-silicate glass comprising
   iia) at least one oxide of silicon;
   iib) at least one oxide of lead;
   iic) at least one chloride;
   iid) optionally at least one further oxide being different from components iia) and iib);
iii) an organic vehicle.

Surprisingly it has been discovered that the incorporation of halogenides into lead-silicate glasses known form the prior art leads to glasses that, when being used as a component in a silver paste, enables a significant reduction of the firing temperature of these pastes. Using these pastes for the formation of electrodes on the front and/or the back side of a Si wafer enables the formation of solar cells that are characterized by an outstanding efficiency.

### Silver Particles i)

The silver particles i) that are present in the paste according to the present invention give metallic conductivity to the solid electrode which is formed when the paste is sintered on firing.

As additional constituents of the silver particles i), those constituents which contribute to more favourable sintering properties, electrical contact, adhesion and electrical conductivity of the formed electrodes are preferred according to the invention. All additional constituents known to the person skilled in the art and which he considers to be suitable in the context of the invention can be employed in the silver particles i). Those additional substituents which represent complementary dopants for the face to which the paste is to be applied are preferred according to the invention. When forming an electrode interfacing with an n-type doped Si layer, additives capable of acting as n-type dopants in Si are preferred. Preferred n-type dopants in this context are group 15 elements or compounds which yield such elements on firing. Preferred group 15 elements in this context according to the invention are P and Bi. When forming an electrode interfacing with a p-type doped Si layer, additives capable of acting as p-type dopants in Si are preferred. Preferred p-type dopants are group 13 elements or compounds which yield such elements on firing. Preferred group 13 elements in this context according to the invention are B and Al.

It is well known to the person skilled in the art that silver particles can exhibit a variety of shapes, surfaces, sizes, surface area to volume ratios, oxygen content and oxide layers. A large number of shapes are known to the person skilled in the art. Some examples are spherical, angular, elongated (rod or needle like) and flat (sheet like). Silver particles may also be present as a combination of particles of different shapes. Silver particles with a shape, or combination of shapes, which favours advantageous sintering, electrical contact, adhesion and electrical conductivity of the produced electrode are preferred according to the invention. One way to characterise such shapes without considering surface nature is through the parameters length, width and thickness. In the context of the invention the length of a particle is given by the length of the longest spatial displacement vector, both endpoints of which are contained within the particle. The width of a particle is given by the length of the longest spatial displacement vector perpendicular to the length vector defined above both endpoints of which are contained within the particle. The thickness of a particle is given by the length of the longest spatial displacement vector perpendicular to both the length vector and the width vector, both defined above, both endpoints of which are contained within the particle. In one embodiment according to the invention, silver particles with as uniform a shape as possible are preferred i.e. shapes in which the ratios relating the length, the width and the thickness are as close as possible to 1, preferably all ratios lying in a range from about 0.7 to about 1.5, more preferably in a range from about 0.8 to about 1.3 and most preferably in a range from about 0.9 to about 1.2. Examples of preferred shapes for the silver particles i) in this embodinvent are therefore spheres and cubes, or combinations thereof, or combinations of one or more thereof with other shapes. In one embodiment of the invention, the silver particles in the paste are spherical. In another embodiment according to the invention, silver particles i) are preferred which have a shape of low uniformity, preferably with at least one of the ratios relating the dimensions of length, width and thickness being above about 1.5, more preferably above about 3 and most preferably above about 5. Preferred shapes according to this embodiment are flake shaped, rod or needle shaped, or a combination of flake shaped, rod or needle shaped with other shapes.

A variety of surface types are known to the person skilled in the art. Surface types which favour effective sintering and yield advantageous electrical contact and conductivity of produced electrodes are favoured for the surface type of the silver particles i) according to the invention.

The particle diameter d₅₀ and the associated values d₁₀ and d₉₀ are characteristics of particles well known to the person skilled in the art. It is preferred according to the invention that the average particle diameter d₅₀ of the silver particles i) lie in a range from about 0.1 to about 10 μm, more preferably in a range from about 1 to about 10 μm and most preferably in a range from about 1 to about 5 μm. The determination of the particle diameter d₅₀ is well known to a person skilled in the art. In one embodiment of the invention, the silver particles i) have a d₅₀ in a range from about 0.5 to about 4 μm, preferably in a range from about 1 to about 3.5 μm, more preferably in a range from about 1 to about 2 μm.

The silver particles i) may be present with a surface coating. Any such coating known to the person skilled in the art and which he considers to be suitable in the context of the invention can be employed on the silver particles. Preferred coatings according to the invention are those coatings which promote improved printing, sintering and etching characteristics of the paste. If such a coating is present, it is preferred according to the invention for that coating to correspond to no more than about 8 wt. %, preferably no more than about 5 wt. %, most preferably no more than about 1 wt. %, in each case based on the total weight of the silver particles.

### Particulate Lead-Silicate Glass ii)

The particulate lead-silicate glass ii), preferably the particulate lead-silicate glass frit ii), comprises at least one oxide of silicon iia), at least one oxide of lead iib), at least one chloride iic) and optionally at least one further oxide iid) being different from components iia) and iib). Preferably, the particulate lead-silicate glass ii) is made of at least these components iia), iib), iic) and optionally iid).

The at least one oxide of silicon iia) is preferably SiO₂.

The at least one oxide of lead iib) can be any oxide of lead, such as PbO, PbO₂, Pb₃O₄ or a mixture of at least two of these oxides.

The at least one chloride iib) can be any compound comprising at least one cation and at least one chloride anion. Particularly suitable as cation component are cations of those metals that are already provided with components iia) and iib) or, as described later, with component iid). Suitable chlorides preferably have a boiling point or sublimation point higher than at least 300° C., more preferably at least 500° C. Examples of suitable chlorides are MnCl₂, ZnCl₂, AgCl, PbCl₂, CrCl₂, CrCl₃, FeCl₂, FeCl₃, CoCl₂, NiCl₂, CuCl, CuCl₂, LiCl, NaCl, KCl, RbCl, CsCl, MgCl₂, CaCl₂, SrCl₂, BaCl₂, SnCl₂, LaCl₃ and a mixture of at least two of these chlorides, wherein LiCl, NaCl, KCl, MgCl₂, CaCl₂, SrCl₂, BaCl₂, ZnCl₂, PbCl₂, AgCl, CrCl₃, MnCl₂, LaCl₃ and mixtures of at least two of these chlorides are particularly preferred.

The particulate lead-silicate glass ii) may comprise, as component iid) at least one further oxide being different from components iia) and iib), wherein at least one further oxide iid) being different from components iia) and iib) is preferably an oxide selected from the group consisting of the oxides of aluminium, boron, phosphorus, titanium, zirconium, cerium, lanthanum, vanadium, niobium, tantalum, chromium, molybdenum, tungsten, manganese, iron, cobalt, nickel, copper, zinc, silver, lithium, sodium, potassium, rubidium, caesium, magnesium, calcium, strontium, barium, tin, bismuth, or a mixture of at least two, at least three or at least four of these oxides.

According to a particularly preferred embodiment of the particulate lead-silicate glass ii) the glass comprises, as component iid), at least one further oxide selected from the group consisting of Al₂O₃, B₂O₃, Li₂O, P₂O₅, ZrO₂, TiO₂, V₂O₅, Ta₂O₅, Nb₂O₅, MoO₃, WO₃, MnO, ZnO, Bi₂O₃, MgO, SrO, BaO and a mixture of at least two, at least three or at least four of these oxides.

According to a preferred embodiment of the particulate lead-silicate glass ii) the glass comprises
iia) at least 5 mol %, preferably at least 10 mol % and more preferably at least 15 mol % of the at least one oxide of silicon, preferably SiO₂;
iib) 25 to 80 mol %, preferably 30 to 75 mol % and more preferably 35 to 70 mol % of at least one oxide of lead, preferably PbO, PbO₂, Pb₃O₄ or a mixture of at least two of these oxides;
iic) 0.1 to 50 mol %, preferably 1 to 25 mol % and more preferably 2 to 10 mol % of the at least one chloride;
iid) 1 to 40 mol %, more preferably 3 to 30 mol % and more preferably 5 to 20 mol % of the at least one further oxide being different from components iia) and iib);
   wherein the amounts are in each case based on the total mole number of components iia) to iid) in the glass and sum up to 100 mol %.

In this context it is particularly preferred that the relative molar ratio of chloride ions to the oxygen ions in the particulate lead-silicate glass ii) Cl⁻:O²⁻ is in the range from 0.001 to 1.5, preferably in the range from 0.01 to 0.5 and even more preferably in the range from 0.01 to 0.05 (example: if a certain amount of glass comprises 1 mol chloride ions and 10 mol oxygen ions, Cl⁻:O²⁻ is 1:10=0.1).

According to a particular embodiment of the particulate lead-silicate glass ii) that is used in the paste according to the present invention comprises less than 0.1 mol %, more preferably less than 0.01 mol % and even more preferably less than 0.001 mol % of elemental silver, based on the total mole number of the components (i. e. oxides and silver compounds) of the particulate lead-silicate glass ii), wherein according to one embodiment of the particulate lead-silicate glass ii) the glass does not comprise any elemental silver at all.

The particulate lead-silicate glass ii) is preferably obtainable by mixing the above described components iia), iib), iic) and optionally iid), melting the thus obtained mixture, cooling the thus obtained glass, preferably to a temperature below 100° C., more preferably to room temperature, and subjecting it to pulverization. In such a process components iia) to iic) and optionally iid) of the particulate lead-silicate glass are melted together.

The step of melting the components is conducted to disconnect the bonding between the molecules in the individual components to lose the properties peculiar to the metal oxides iib) and iid), so that the melted components are homogeneously mixed together to provide the vitric properties through the subsequent cooling step. In the melting step, the melting temperature may be selected without specific limitation as the temperature at which all the individual components are sufficiently melted. For example, the melting temperature may be in the range from 800 to 1200° C. Further, the melting time may be determined, without specific limitation, as the time period during which all the components are sufficiently melted at the above-defined melting temperature, and selected appropriately depending on the types of the components and the melting temperature. For example, the melting time may be, if not specifically limited to, depending mainly on composition, temperature, and batch size, about 10 minutes to about two or three hours.

The melted mixture is then cooled down to acquire a lead-silicate glass in a solid state. Generally, the fast cooling for the melted mixture is preferred. A low cooling rate may cause crystallization during the cooling step, consequently with the failure to form the glass phase. As a means for acquiring such a high cooling rate, the typical methods known in the related art may be used, such as, if not specifically limited to, conducting an extrusion of the melted mixture into a sheet to increase the surface area, e. g. roller quenching, or immersion in water.

Subsequently, the solid lead-silicate glass is ground into powder comprising particles of the glass. The average particles diameter d₅₀, and the associated parameters d₁₀ and d₉₀ are characteristics of particles well known to the person skilled in the art. It is preferred according to the invention that the average particle diameter d₅₀ of the particulate lead-silicate glass ii) lies in a range from about 0.1 to about 15 μm, more preferably in a range from about 0.2 to about 7 μm and most preferably in a range from about 0.5 to about 5 μm. In one embodiment of the invention, the particulate lead-silicate glass ii) has a d₅₀ in a range from about 0.1 to about 3 μm, preferably in a range from about 0.5 to about 2 μm, more preferably in a range from about 0.8 to about 1.5 μm.

To pulverize the lead-silicate glass ii) obtained by the cooling step into a powder may include any typical comminution method known in the related art. For efficiency, the comminution process may be carried out in two stages. In this case, the first and second comminution stages may involve a repetition of the same process; otherwise, the first comminution is crushing, and the secand comminution is fine grinding. The term “crushing” as used herein refers to comminution of the solid glass to such a particle size adequate to the subsequent fine-grinding method to facilitate the fine-grinding process, rather than limiting the particle size to a given average particle diameter. The term “fine-grinding” as used herein refers to comminution of the crushed glass into glass powder having a desired average particle diameter.

In one embodiment of the paste according to the present invention, the particles of the lead-silicate glass ii) have a specific surface area in the range from about 0.01 to about 25 m²/g, preferably in the range from about 0.1 to about 20 m²/g, more preferably in the range from about 1 to about 15 m²/g.

Organic Vehicle iii)

Preferred organic vehicles iii) in the context of the invention are solutions, emulsions or dispersions based on one or more solvents, preferably an organic solvent, which ensure that the constituents of the paste are present in a dissolved, emulsified, or dispersed form. Preferred organic vehicles iii) are those which provide optimal stability of constituents within the paste and endow the paste with a viscosity allowing effective line printability. Preferred organic vehicles iii) according to the invention comprise as vehicle components:
(iiia) a binder, preferably in a range from about 1 to about 10 wt %, more preferably in a range from about 2 to about 8 wt % and most preferably in a range from about 3 to about 7 wt %;
(iiib) a surfactant, preferably in a range from about 0 to about 10 wt. %, more preferably in a range from about 0 to about 8 wt % and most preferably in a range from about 0.01 to about 6 wt %;
(iiic) one or more solvents, the proportion of which is determined by the proportions of the other constituents in the organic vehicle;
(iiic) optional additives, preferably in range from about 0 to about 10 wt %, more preferably in a range from about 0 to about 8 wt % and most preferably in a range from about 1 to about 5 wt %;
   wherein the wt. % are each based on the total weight of the organic vehicle and add up to 100 wt %. According to the invention preferred organic vehicles iii) are those which allow for the preferred high level of printability of the paste described above to be achieved.
   Binder iiia)

Preferred binders in the context of the invention are those which contribute to the formation of a paste with favourable stability, printability, viscosity, sintering and etching properties. Binders are well known to the person skilled in the art. All binders which are known to the person skilled in the art and which he considers to be suitable in the context of this invention can be employed as the binder in the organic vehicle iii). Preferred binders according to the invention (which often fall within the category termed “resins”) are polymeric binders, monomeric binders, and binders which are a combination of polymers and monomers. Polymeric binders can also be copolymers wherein at least two different monomeric units are contained in a single molecule. Preferred polymeric binders are those which carry functional groups in the polymer main chain, those which carry functional groups off of the main chain and those which carry functional groups both within the main chain and off of the main chain. Preferred polymers carrying functional groups in the main chain are for example polyesters, substituted polyesters, polycarbonates, substituted polycarbonates, polymers which carry cyclic groups in the main chain, poly-sugars, substituted poly-sugars, polyurethanes, substituted polyurethanes, polyamides, substituted polyamides, phenolic resins, substituted phenolic resins, copolymers of the monomers of one or more of the preceding polymers, optionally with other co-monomers, or a combination of at least two thereof. Preferred polymers which carry cyclic groups in the main chain are polyvinylbutylate (PVB) and its derivatives and poly-terpineol and its derivatives or mixtures thereof. Preferred poly-sugars are for example cellulose and alkyl derivatives thereof, preferably methyl cellulose, ethyl cellulose, propyl cellulose, butyl cellulose and their derivatives and mixtures of at least two thereof. Preferred polymers which carry functional groups off of the main polymer chain are those which carry amide groups, those which carry acid and/or ester groups, often called acrylic resins, or polymers which carry a combination of aforementioned functional groups, or a combination thereof. Preferred polymers which carry amide off of the main chain are for example polyvinyl pyrrolidone (PVP) and its derivatives. Preferred polymers which carry acid and/or ester groups off of the main chain are for example polyacrylic acid and its derivatives, polymethacrylate (PMA) and its derivatives or polymethylmethacrylate (PMMA) and its derivatives, or a mixture thereof. Preferred monomeric binders according to the invention are ethylene glycol based monomers, terpineol resins or rosin derivatives, or a mixture thereof. Preferred monomeric binders based on ethylene glycol are those with ether groups, ester groups or those with an ether group and an ester group, preferred ether groups being methyl, ethyl, propyl, butyl, pentyl hexyl and higher alkyl ethers, the preferred ester group being acetate and its alkyl derivatives, preferably ethylene glycol monobutylether monoacetate or a mixture thereof. Alkyl cellulose, preferably ethyl cellulose, its derivatives and mixtures thereof with other binders from the preceding lists of binders or otherwise are the most preferred binders in the context of the invention.

Surfactant iiib)

Preferred surfactants in the context of the invention are those which contribute to the formation of a paste with favourable stability, printability, viscosity, sintering and etching properties. Surfactants are well known to the person skilled in the art. All surfactants which are known to the person skilled in the art and which he considers to be suitable in the context of this invention can be employed as the surfactant in the organic vehicle iii). Preferred surfactants in the context of the invention are those based on linear chains, branched chains, aromatic chains, fluorinated chains, siloxane chains, polyether chains and combinations thereof. Preferred surfactants are single chained double chained or poly chained. Preferred surfactants according to the invention have non-ionic, anionic, cationic, or zwitterionic heads. Preferred surfactants are polymeric and monomeric or a mixture thereof. Preferred surfactants according to the invention can have pigment affinic groups, preferably hydroxyfunctional carboxylic acid esters with pigment affinic groups (e.g., DISPERBYK®-108, manufactured by BYK USA, Inc.), acrylate copolymers with pigment affinic groups (e.g., DISPERBYK®-116, manufactured by BYK USA, Inc.), modified polyethers with pigment affinic groups (e.g., TEGO® DISPERS 655, manufactured by Evonik Tego Chemie GmbH), other surfactants with groups of high pigment affinity (e.g., TEGO® DISPERS 662 C, manufactured by Evonik Tego Chemie GmbH). Other preferred polymers according to the invention not in the above list are polyethyleneglycol and its derivatives, and alkyl carboxylic acids and their derivatives or salts, or mixtures thereof. The preferred polyethyleneglycol derivative according to the invention is poly(ethylene-glycol)acetic acid. Preferred alkyl carboxylic acids are those with fully saturated and those with singly or poly unsaturated alkyl chains or mixtures thereof. Preferred carboxylic acids with saturated alkyl chains are those with alkyl chains lengths in a range from about 8 to about 20 carbon atoms, preferably C₉H₁₉COOH (capric acid), C₁₁H₂₃COOH (Lauric acid), C₁₃H₂₇COOH (myristic acid) C₁₅H₃₁COOH (palmitic acid), C₁₇H₃₅COOH (stearic acid) or mixtures thereof. Preferred carboxylic acids with unsaturated alkyl chains are C₁₈H₃₄O₂ (oleic acid) and C₁₈H₃₂O₂ (linoleic acid). The preferred monomeric surfactant according to the invention is benzotriazole and its derivatives.

Solvent iiic)

Preferred solvents according to the invention are constituents of the electro-conductive paste which are removed from the paste to a significant extent during firing, preferably those which are present after firing with an absolute weight reduced by at least about 80% compared to before firing, preferably reduced by at least about 95% compared to before firing. Preferred solvents according to the invention are those which allow an electro-conductive paste to be formed which has favourable viscosity, printability, stability and sintering characteristics and which yields electrodes with favourable electrical conductivity and electrical contact to the substrate. Solvents are well known to the person skilled in the art. All solvents which are known to the person skilled in the art and which he considers to be suitable in the context of this invention can be employed as the solvent in the organic vehicle. According to the invention preferred solvents are those which allow the preferred high level of printability of the electro-conductive paste as described above to be achieved. Preferred solvents according to the invention are those which exist as a liquid under standard ambient temperature and pressure (SATP) (298.15 K, 100 kPa), preferably those with a boiling point above about 90° C. and a melting point above about −20° C. Preferred solvents according to the invention are polar or non-polar, protic or aprotic, aromatic or non-aromatic. Preferred solvents according to the invention are mono-alcohols, di-alcohols, poly-alcohols, monoesters, di-esters, poly-esters, mono-ethers, di-ethers, poly-ethers, solvents which comprise at least one or more of these categories of functional group, optionally comprising other categories of functional group, preferably cyclic groups, aromatic groups, unsaturated-bonds, alcohol groups with one or more O atoms replaced by heteroatoms, ether groups with one or more O atoms replaced by heteroatoms, esters groups with one or more O atoms replaced by heteroatoms, and mixtures of two or more of the aforementioned solvents. Preferred esters in this context are dialkyl esters of adipic acid, preferred alkyl constituents being methyl, ethyl, propyl, butyl, pentyl, hexyl and higher alkyl groups or combinations of two different such alkyl groups, preferably dimethyladipate, and mixtures of two or more adipate esters. Preferred ethers in this context are di-ethers, preferably dialkyl ethers of ethylene glycol, preferred alkyl constituents being methyl, ethyl, propyl, butyl, pentyl, hexyl and higher alkyl groups or combinations of two different such alkyl groups, and mixtures of two diethers. Preferred alcohols in this context are primary, secondary and tertiary alcohols, preferably tertiary alcohols, terpineol and its derivatives being preferred, or a mixture of two or more alcohols. Preferred solvents which combine more than one different functional groups are 2,2,4-trimethyl-1,3-pentanediol monoisobutyrate, often called texanol, and its derivatives, 2-(2-ethoxyethoxy)ethanol, often known as carbitol, its alkyl derivatives, preferably methyl, ethyl, propyl, butyl, pentyl, and hexyl carbitol, preferably hexyl carbitol or butyl carbitol, and acetate derivatives thereof, preferably butyl carbitol acetate, or mixtures of at least 2 of the aforementioned.

Additives in the Organic Vehicle iiid)

Preferred additives in the organic vehicle are those additives which are distinct from the aforementioned vehicle components and which contribute to favourable properties of the paste, such as advantageous viscosity, sintering, electrical conductivity of the produced electrode and good electrical contact with substrates. All additives known to the person skilled in the art and which he considers to be suitable in the context of the invention can be employed as additive in the organic vehicle iii). Preferred additives according to the invention are thixotropic agents, viscosity regulators, stabilising agents, inorganic additives, thickeners, emulsifiers, dispersants or pH regulators. Preferred thixotropic agents in this context are carboxylic acid derivatives, preferably fatty acid derivatives or combinations thereof. Preferred fatty acid derivatives are C₉H₁₉COOH (capric acid), C₁₁H₂₃COOH (Lauric acid), C₁₃H₂₇COOH (myristic acid) C₁₅H₃₁COOH (palmitic acid), C₁₇H₃₅COOH (stearic acid) C₁₈H₃₄O₂ (oleic acid), C₁₈H₃₂O₂ (linoleic acid) or combinations thereof. A preferred combination comprising fatty acids in this context is castor oil.

### Additives iv)

The paste according to the present invention may, in addition to components i) to iii), comprises further additives iv) being different from the components mentioned above. Preferred additives in the context of the invention are constituents added to the paste, in addition to the other constituents explicitly mentioned, which contribute to increased performance of the paste, of the electrodes produced thereof or of the resulting solar cell. All additives known to the person skilled in the art and which he considers suitable in the context of the invention can be employed as additive in the paste. In addition to additives present in the vehicle, additives can also be present in the paste. Preferred additives according to the invention are thixotropic agents, viscosity regulators, emulsifiers, stabilising agents or pH regulators, inorganic additives, thickeners and dispersants or a combination of at least two thereof, whereas inorganic additives are most preferred. Preferred inorganic additives in this context according to the invention are Mg, Ni, Te, W, Zn, Mg, Gd, Ce, Zr, Ti, Mn, Sn, Ru, Co, Fe, Cu and Cr or a combination of at least two thereof, preferably Zn, Sb, Mn, Ni, W, Te and Ru or a combination of at least two thereof, oxides thereof, compounds which can generate those metal oxides on firing, or a mixture of at least two of the aforementioned metals, a mixture of at least two of the aforementioned oxides, a mixture of at least two of the aforementioned compounds which can generate those metal oxides on firing, or mixtures of two or more of any of the above mentioned.

According to a preferred embodiment of the paste according to the present invention the paste comprises
i) at least 60 wt %, preferably at least 70 wt % and more preferably at least 80 wt % of the silver particles;
ii) 0.5 to 10 wt %, preferably 0.75 to 8 wt % and more preferably 1 to 5 wt % of the particulate lead-silicate glass;
iii) 5 to 25 wt %, preferably 6 to 20 wt % and more preferably 7 to 15 wt % of the organic vehicle;
iv) up to 10 wt %, preferably up to 5 wt % and more preferably up to 2.5 wt % of further additives being different from components i) to iii);
   wherein the amounts are in each case based on the total weight of the paste and sum up to 100 wt %.

The paste according to the present invention can be prepared by mixing the silver particles i), preferably in the form of a silver powder, the particulate lead-silicate glass ii), also preferably present in the form of a glass powder, the organic vehicle iii) and optionally the further additives iv) in any order. In some embodiments, the inorganic materials are mixed first, and they are then added to the organic medium. In other embodiments, the silver powder which is the major portion of the inorganics is slowly added to the organic medium. The viscosity of the paste is typically in the range of 5 to 75 Pas, preferably in the range from 5 to about 35 Pas, more preferably in a range from about 10 to about 25 Pas and most preferably in a range from about 15 to about 20 Pas. The viscosity can be adjusted, if needed, by the addition of solvents. Mixing methods that provide high shear are useful.

A contribution towards achieving at least one of the above mentioned objects is also made by a solar cell precursor comprising the following solar cell precursor constituents:
a) a wafer having a front side and a back side;
b) a paste according to the present invention superimposed on at least one side of the wafer, the at least one side being selected from the group consisting of the front side and the back side.

### Wafers

The solar cell precursor comprises, as component a), a wafer. Preferred wafers according to the invention are regions among other regions of the solar cell capable of absorbing light with high efficiency to yield electron-hole pairs and separating holes and electrons across a boundary with high efficiency, preferably across a so called p-n junction boundary. Preferred wafers according to the invention are those comprising a single body made up of a doped layer at the front side and a doped layer at the back side.

It is preferred for that wafer to consist of appropriately doped tetravalent elements, binary compounds, tertiary compounds or alloys. Preferred tetravalent elements in this context are Si, Ge or Sn, preferably Si. Preferred binary compounds are combinations of two or more tetravalent elements, binary compounds of a group III element with a group V element, binary compounds of a group II element with a group VI element or binary compounds of a group IV element with a group VI element. Preferred combinations of tetravalent elements are combinations of two or more elements selected from Si, Ge, Sn or C, preferably SiC. The preferred binary compounds of a group III element with a group V element is GaAs. It is most preferred according to the invention for the wafer to be based on Si. Si, as the most preferred material for the wafer, is referred to explicitly throughout the rest of this application. Sections of the following text in which Si is explicitly mentioned also apply for the other wafer compositions described above.

Where the front doped layer and back doped layer of the wafer meet is the p-n junction boundary. In an n-type solar cell, the back doped layer is doped with electron donating n-type dopant and the front doped layer is doped with electron accepting or hole donating p-type dopant. In a p-type solar cell, the back doped layer is doped with p-type dopant and the front doped layer is doped with n-type dopant. It is preferred according to the invention to prepare a wafer with a p-n junction boundary by first providing a doped Si substrate and then applying a doped layer of the opposite type to one face of that substrate. In another embodiment of the invention the p-doped layer and a n-doped layer can be arranged at the same face of the wafer. This wafer design is often called interdigitated back contact as exemplified in Handbook of Photovoltaic Science and Engineering, 2^{nd} Edition, John Wiley & Sons, 2003, chapter 7.

Doped Si substrates are well known to the person skilled in the art. The doped Si substrate can be prepared in any way known to the person skilled in the art and which he considers to be suitable in the context of the invention. Preferred sources of Si substrates according to the invention are mono-crystalline Si, multi-crystalline Si, amorphous Si and upgraded metallurgical Si, mono-crystalline Si or multi-crystalline Si being most preferred. Doping to form the doped Si substrate can be carried out simultaneously by adding dopant during the preparation of the Si substrate or can be carried out in a subsequent step. Doping subsequent to the preparation of the Si substrate can be carried out for example by gas diffusion epitaxy. Doped Si substrates are also readily commercially available. According to the invention it is one option for the initial doping of the Si substrate to be carried out simultaneously to its formation by adding dopant to the Si mix. According to the invention it is one option for the application of the front doped layer and the highly doped back layer, if present, to be carried out by gas-phase epitaxy. This gas phase epitaxy is preferably carried out at a temperature in a range from about 500° C. to about 900° C., more preferably in a range from about 600° C. to about 800° C. and most preferably in a range from about 650° C. to about 750° C. at a pressure in a range from about 2 kPa to about 100 kPa, preferably in a range from about 10 to about 80 kPa, most preferably in a range from about 30 to about 70 kPa.

It is known to the person skilled in the art that Si substrates can exhibit a number of shapes, surface textures and sizes. The shape can be one of a number of different shapes including cuboid, disc, wafer and irregular polyhedron amongst others. The preferred shape according to the invention is wafer shaped where that wafer is a cuboid with two dimensions which are similar, preferably equal and a third dimension which is significantly less than the other two dimensions. Significantly less in this context is preferably at least a factor of about 100 smaller.

A variety of surface types are known to the person skilled in the art. According to the invention Si substrates with rough surfaces are preferred. One way to assess the roughness of the substrate is to evaluate the surface roughness parameter for a sub-surface of the substrate which is small in comparison to the total surface area of the substrate, preferably less than one hundredth of the total surface area, and which is essentially planar. The value of the surface roughness parameter is given by the ratio of the area of the subsurface to the area of a theoretical surface formed by projecting that subsurface onto the flat plane best fitted to the subsurface by minimising mean square displacement. A higher value of the surface roughness parameter indicates a rougher, more irregular surface and a lower value of the surface roughness parameter indicates a smoother, more even surface. According to the invention, the surface roughness of the Si substrate is preferably modified so as to produce an optimum balance between a number of factors including but not limited to light absorption and adhesion of fingers to the surface.

The two larger dimensions of the Si substrate can be varied to suit the application required of the resultant solar cell. It is preferred according to the invention for the thickness of the Si wafer to lie below about 0.5 mm more preferably below about 0.3 mm and most preferably below about 0.2 mm. Some wafers have a minimum size of about 0.01 mm or more.

It is preferred according to the invention for the front doped layer to be thin in comparison to the back doped layer. In one embodiment of the invention, the p-doped layer has a thickness in a range from about 10 nm to about 4 μm, preferably in a range from about 50 nm to about 1 μm and most preferably in a range from about 100 to about 800 nm.

The front doped layer is commonly thinner than the back doped layer. In one embodiment of the invention, the back face comprises an n-doped layer which has a greater thickness than the p-doped layer.

A highly doped layer can be applied to the back face of the Si substrate between the back doped layer and any further layers. Such a highly doped layer is of the same doping type as the back doped layer and such a layer is commonly denoted with a + (n⁺-type layers are applied to n-type back doped layers and p⁺-type layers are applied to p-type back doped layers). This highly doped back layer serves to assist metallisation and improve electro-conductive properties at the substrate/electrode interface area. It is preferred according to the invention for the highly doped back layer, if present, to have a thickness in a range from about 10 nm to about 30 μm, preferably in a range from about 50 nm to about 20 μm and most preferably in a range from about 100 nm to about 10 μm.

### Dopants

Preferred dopants are those which, when added to the Si wafer, form a p-n junction boundary by introducing electrons or holes into the band structure. It is preferred according to the invention that the identity and concentration of these dopants be specifically selected so as to tune the band structure profile of the p-n junction and set the light absorption and conductivity profiles as required. Preferred p-type dopants according to the invention are those which add holes to the Si wafer band structure. They are well known to the person skilled in the art. All dopants known to the person skilled in the art and which he considers to be suitable in the context of the invention can be employed as p-type dopant. Preferred p-type dopants according to the invention are trivalent elements, particularly those of group 13 of the periodic table. Preferred group 13 elements of the periodic table in this context include but are not limited to B, Al, Ga, In, Tl or a combination of at least two thereof, wherein B is particularly preferred. In one embodiment of the invention, the p-doped layer comprises B as a dopant.

Preferred n-type dopants according to the invention are those which add electrons to the Si wafer band structure. They are well known to the person skilled in the art. All dopants known to the person skilled in the art and which he considers to be suitable in the context of the invention can be employed as n-type dopant. Preferred n-type dopants according to the invention are elements of group 15 of the periodic table. Preferred group 15 elements of the periodic table in this context include N, P, As, Sb, Bi or a combination of at least two thereof, wherein P is particularly preferred. In one embodiment of the invention, the n-doped layer comprises P as dopant.

As described above, the various doping levels of the p-n junction can be varied so as to tune the desired properties of the resulting solar cell.

According to the invention, it is preferred for the back doped layer to be lightly doped, preferably with a dopant concentration in a range from about 1×10¹³ to about 1×10¹⁸ cm⁻³, preferably in a range from about 1×10¹⁴ to about 1×10¹⁷ cm⁻³, most preferably in a range from about 5×10¹⁵ to about 5×10¹⁶ cm⁻³. Some commercial products have a back doped layer with a dopant concentration of about 1×10¹⁶.

In one embodiment of the invention, the highly doped back layer (if one is present) is highly doped, preferably with a concentration in a range from about 1×10¹⁷ to about 5×10²¹ cm⁻³, more preferably in a range from about 5×10¹⁷ to about 5×10²⁰ cm⁻³, and most preferably in a range from about 1×10¹⁸ to about 1×10²⁰ cm⁻³.

### Printing

The solar cell precursor comprises, as component b), a paste according to the present invention that is superimposed on at least one side of the wafer. It is preferred according to the invention that the front and/or back electrodes are applied to a Si wafer by applying the paste according to the present invention to the corresponding side of the Si wafer and then firing said paste to obtain a sintered body. The paste can be applied in any manner known to the person skilled in that art and which he considers suitable in the context of the invention including but not limited to impregnation, dipping, pouring, dripping on, injection, spraying, knife coating, curtain coating, brushing or printing or a combination of at least two thereof, wherein preferred printing techniques are ink-jet printing, screen printing, tampon printing, offset printing, relief printing or stencil printing or a combination of at least two thereof. It is preferred according to the invention that the paste is applied by printing, preferably by screen printing. In one embodiment of the invention, the paste is applied to the front face through a screen. In one aspect of this embodiment the application through a screen satisfies at least one of the following parameters:
mesh count in a range from about 290 to about 400, preferably in a range from about 310 to about 390, more preferably in a range from about 330 to about 370;
wire thickness in a range from about 10 to about 30 μm, preferably in a range from about 12 to about 25 μm, more preferably in a range from about 14 to about 18 μm;
Emulsion over mesh (EoM) thickness in a range from about 5 to about 25 μm, preferably in a range from about 10 to about 20 μm, more preferably in a range from about 13 to about 18 μm;
finger spacing depends on the silicon wafer that is used and is usually in a range from about 1 to about 3 mm.

In one embodiment of the invention, the paste is superimposed on the front face in a grid pattern. In one aspect of this embodiment, this grid pattern comprises fingers with a width in a range from about 20 to about 100 μm, preferably in a range from about 30 to about 80 μm, more preferably in a range from about 30 to about 50 μm and bus bars at an angle thereto in a range from about 70 to about 90°, these bus bars having a width in a range from about 0.5 to about 2.5 mm, preferably in a range from about 1 to about 2 mm, more preferably in a range from about 1.3 to about 1.8 mm.

In a further embodiment of the invention, the paste is superimposed on the back face in a grid pattern. In one aspect of this embodiment, this grid pattern comprises fingers with a width in a range from about 20 to about 180 μm, preferably in a range from about 30 to about 100 μm, more preferably in a range from about 40 to about 60 μm and bus bars at an angle thereto in a range from about 70 to about 90°, these bus bars having a width in a range from about 0.5 to about 2.5 mm, preferably in a range from about 1 to about 2 mm, more preferably in a range from about 1.3 to about 1.8 mm.

According to one embodiment of the solar cell precursor according to the present invention the wafer is an n-type doped Si wafer and the paste is superimposed on the front side, on the back side or on both sides of the wafer, i. e. on the front side and the back side.

According to another embodiment of the solar cell precursor according to the present invention the wafer is a p-type doped Si wafer and the paste is superimposed on the front side.

A contribution towards achieving at least one of the above mentioned objects is also made by a process for the preparation of a solar cell comprising the following preparation steps:
A) provision of a solar cell precursor according to the present invention;
B) firing of the solar cell precursor to obtain a solar cell.

### Firing

It is preferred according to the invention for electrodes to be formed by superimposing the font or the back surface of a wafer with the paste according to the present invention (thereby forming the solar cell precursor according to the present invention) and then to fire said paste to yield a solid electrode body. Firing is well known to the person skilled in the art and can be carried out in any manner known to him and which he considers suitable in the context of the invention. Firing must be carried out above the glass transition temperature of the particulate lead-silicon glass ii) in the paste (and, if further glass frits should be comprised in the paste having a glass transition temperature higher than the particulate lead-silicate glass ii), must be carried out above the glass transition temperature of such glass frits).

In one embodiment of the present invention, the firing stage satisfies at least one of the following criteria:
holding temperature in process step B) measured according to the method titled “temperature profile in the firing furnace” given below, in a range from about 660 to about 760° C., preferably in a range from about 680 to about 740° C.;
time at the holding temperature in a range from about 1 s to about 5 minutes.

It is preferred according to the invention for firing to be carried out with a process time in a range from about 10 s to about 2 minutes, more preferably in a range from about 25 s to about 90 s and most preferably in a range from about 40 s to about 1 minute.

If the paste according to the present invention is used for the formation of a solid electrode either on the front or the back surface of the solar cell, the paste according to the present invention is applied to the corresponding surface as described above and is then fired under the conditions described above. However, according to a particular embodiment of the process according to the present invention the paste according to the present invention is used for the formation of both, the front and the back side electrode. For that purpose, the paste according to the present invention is applied on the front and the back surface and the layers of pastes are then simultaneously fired under the conditions described above.

A contribution to achieving at least one of the above described objects is made by a solar cell obtainable by a process according to the invention. The solar cell according to the present invention can be any silicon solar cell, for example an amorphous silicon cell, a monocrystalline cell, a multicrystalline cell, an amorphous silicon-polycrystalline silicon tandem cell, a silicon-silicon/germanium tandem cell, a string ribbon cell, a EFG (edge-defined film-fed-grown) cell, a PESC (passivated emitter solar cell), a PERC (passivated emitter, rear cell), a PERL (passivated emitter, rear locally diffused) cell or a standard BSF cell. However, preferred solar cells according to the invention are those which have a high efficiency in terms of proportion of total energy of incident light converted into electrical energy output and which are light and durable, particularly preferably an n-type solar cell. As exemplified in FIG. 2, one layer configuration for the solar cell is as follows: (i) Front electrode, (ii) Anti reflection coating, (iii) Front passivation layer, (iv) Front doped layer, (v) p-n junction boundary, (vi) Back doped layer, (vii) Highly doped back layer, (viii) Back passivation layer, (ix) Back electrode. Individual layers can be omitted from this common layer configuration or individual layers can indeed perform the function of more than one of the layers described in the common embodiment outlined above. In one embodiment of the invention, a single layer acts as both anti-reflection layer and passivation layer. As exemplified in FIG. 1, another layer configuration is as follows: (I) Front electrode, (II) Front doped layer, (III) p-n junction boundary, (IV) Back doped layer, (V) Back electrode.

According to the invention, an anti-reflection coating can be applied as the outer and often as the outermost layer before the electrode on the front face of the solar cell. Preferred anti-reflection coatings according to the invention are those which decrease the proportion of incident light reflected by the front face and increase the proportion of incident light crossing the front face to be absorbed by the wafer. Anti-reflection coatings which give rise to a favourable absorption/reflection ratio, are susceptible to etching by the employed electro-conductive paste but are otherwise resistant to the temperatures required for firing of the electro-conductive paste, and do not contribute to increased recombination of electrons and holes in the vicinity of the electrode interface are favoured. All anti-reflection coatings known to the person skilled in the art and which he considers to be suitable in the context of the invention can be employed. Preferred anti-reflection coatings according to the invention are SiNₓ, SiO₂, Al₂O₃, TiO₂ or mixtures of at least two thereof and/or combinations of at least two layers thereof, wherein SiNₓ is particularly preferred, in particular where an Si wafer is employed.

The thickness of anti-reflection coatings is suited to the wavelength of the appropriate light. According to the invention it is preferred for anti-reflection coatings to have a thickness in a range from about 20 to about 300 nm, more preferably in a range from about 40 to about 200 nm and most preferably in a range from about 60 to about 90 nm.

According to the invention, one or more passivation layers can be applied to the front and/or back side as outer or as the outermost layer before the electrode, or before the anti-reflection layer if one is present. Preferred passivation layers are those which reduce the rate of electron/hole recombination in the vicinity of the electrode interface. Any passivation layer which is known to the person skilled in the art and which he considers to be suitable in the context of the invention can be employed. Preferred passivation layers according to the invention are silicon nitride, silicon dioxide and titanium dioxide, silicon nitride being most preferred. According to the invention, it is preferred for the passivation layer to have a thickness in a range from about 0.1 nm to about 2 μm, more preferably in a range from about 10 nm to about 1 μm and most preferably in a range from about 30 nm to about 200 nm.

A single layer can serve as anti-reflection layer and passivation layer. In one embodiment of the invention, one or more layers which act as anti-reflection layer and/or passivation layer are present between the p-doped layer and the superimposed first paste in the solar cell precursor. In one aspect of this embodiment, at least one of the layers which function as anti-reflection layer and/or passivation layer comprises SiNₓ, wherein x stands for a positive but not necessarily whole number.

In addition to the layers described above which directly contribute to the principle function of the solar cell, further layers can be added for mechanical and chemical protection.

The cell can be encapsulated to provide chemical protection. Encapsulations are well known to the person skilled in the art and any encapsulation can be employed which is known to him and which he considers suitable in the context of the invention. According to the invention, transparent polymers, often referred to as transparent thermoplastic resins, are preferred as the encapsulation material, if such an encapsulation is present. Preferred transparent polymers in this context are for example silicon rubber and polyethylene vinyl acetate (PVA).

A transparent glass sheet can be added to the front of the solar cell to provide mechanical protection to the front face of the cell. Transparent glass sheets are well known to the person skilled in the art and any transparent glass sheet known to him and which he considers to be suitable in the context of the invention can be employed as protection on the front face of the solar cell.

A back protecting material can be added to the back face of the solar cell to provide mechanical protection. Back protecting materials are well known to the person skilled in the art and any back protecting material which is known to the person skilled in the art and which he considers to be suitable in the context of the invention can be employed as protection on the back face of the solar cell. Preferred back protecting materials according to the invention are those having good mechanical properties and weather resistance. The preferred back protection material according to the invention is polyethylene terephthalate with a layer of polyvinyl fluoride. It is preferred according to the invention for the back protecting material to be present underneath the encapsulation layer (in the event that both a back protection layer and encapsulation are present).

A frame material can be added to the outside of the solar cell to give mechanical support. Frame materials are well known to the person skilled in the art and any frame material known to the person skilled in the art and which he considers suitable in the context of the invention can be employed as frame material. The preferred frame material according to the invention is aluminium.

A contribution to achieving at least one of the above mentioned objects is made by a module comprising at least two solar cells, at least one of which is a solar cell according to the present invention. A multiplicity of solar cells according to the invention can be arranged spatially and electrically connected to form a collective arrangement called a module. Preferred modules according to the invention can take a number of forms, preferably a rectangular surface known as a solar panel. Large varieties of ways to electrically connect solar cells as well as large varieties of ways to mechanically arrange and fix such cells to form collective arrangements are well known to the person skilled in the art and any such methods known to him and which he considers suitable in the context of the invention can be employed. Preferred methods according to the invention are those which result in a low mass to power output ratio, low volume to power output ration, and high durability. Aluminium is the preferred material for mechanical fixing of solar cells according to the invention.

A contribution to achieving at least one of the above mentioned objects is also made by the use the particulate lead-silicate glass described as component ii) in connection with the paste according to the present invention as a component in a silver paste that can be used for the formation of an electrode, in particular for the formation of a front- and/or back side electrode of a solar cell.

### DESCRIPTION OF THE DRAWINGS

The invention is now explained by means of figures which are intended for illustration only and are not to be considered as limiting the scope of the invention. In brief,

FIG. 1 shows a cross sectional view of the minimum layer configuration for a solar cell;

FIG. 2 shows a cross sectional view a common layer configuration for a solar cell;

FIGS. 3a, 3b and 3c together illustrate the process of firing a front side paste.

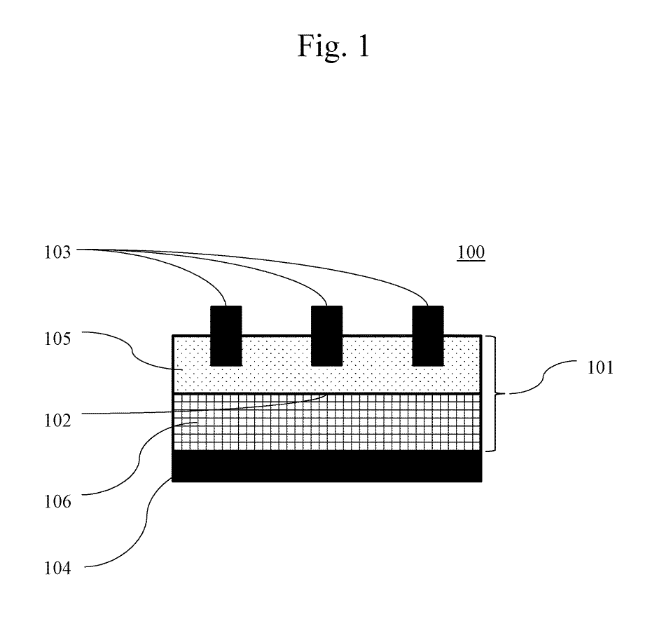

FIG. 1 shows a cross sectional view of a solar cell 100 and represents the minimum required layer configuration for a solar cell according to the invention. Starting from the back face and continuing towards the front face the solar cell 100 comprises a back electrode 104, a back doped layer 106, a p-n junction boundary 102, a front doped layer 105 and a front electrode 103, wherein the front electrode penetrates into the front doped layer 105 enough to form a good electrical contact with it, but not so much as to shunt the p-n junction boundary 102. The back doped layer 106 and the front doped layer 105 together constitute a single doped Si wafer 101. In the case that 100 represents an n-type cell, the back electrode 104 is preferably a silver electrode, the back doped layer 106 is preferably Si lightly doped with P, the front doped layer 105 is preferably Si heavily doped with B and the front electrode 103 is preferably a mixed silver and aluminium electrode. In the case that 100 represents a p-type cell, the back electrode 104 is preferably a mixed silver and aluminium electrode, the back doped layer 106 is preferably Si lightly doped with B, the front doped layer 105 is preferably Si heavily doped with P and the front electrode 103 is preferably a silver electrode. The front electrode 103 has been represented in FIG. 1 as consisting of three bodies purely to illustrate schematically the fact that the front electrode 103 does not cover the front face in its entirety. The invention does not limit the front electrode 103 to those consisting of three bodies.

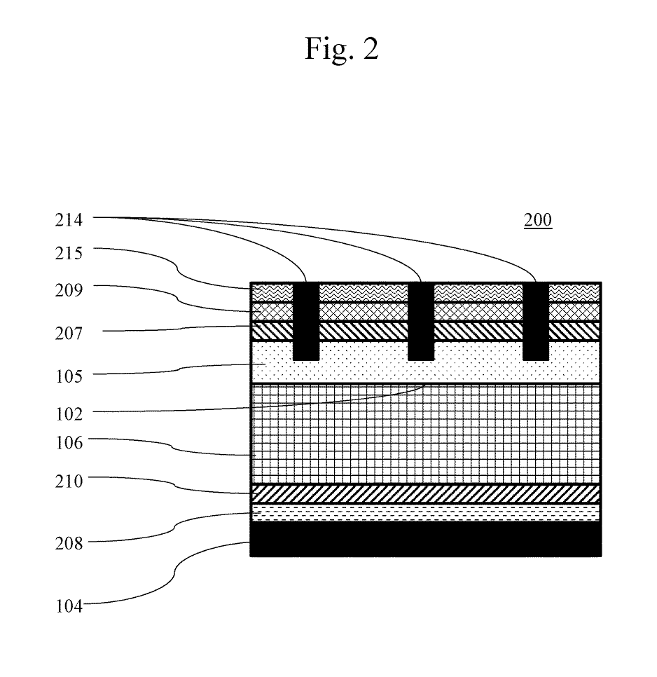

FIG. 2 shows a cross sectional view of a common layer configuration for a solar cell 200 according to the invention (excluding additional layers which serve purely for chemical and mechanical protection). Starting from the back face and continuing towards the front face the solar cell 200 comprises a back electrode 104, a back passivation layer 208, a highly doped back layer 210, a back doped layer 106, a p-n junction boundary 102, a front doped layer 105, a front passivation layer 207, an anti-reflection layer 209, front electrode fingers 214 and front electrode bus bars 215, wherein the front electrode fingers penetrate through the anti-reflection layer 209 and the front passivation layer 207 and into the front doped layer 105 far enough to form a good electrical contact with the front doped layer, but not so far as to shunt the p-n junction boundary 102. In the case that 200 represents an n-type cell, the back electrode 104 is preferably a silver electrode, the highly doped back layer 210 is preferably Si heavily doped with P, the back doped layer 106 is preferably Si lightly doped with P, the front doped layer 105 is preferably Si heavily doped with B, the anti-reflection layer 209 is preferably a layer of silicon nitride and the front electrode fingers and bus bars 214 and 215 are preferably a mixture of silver and aluminium. In the case that 200 represents a p-type cell, the back electrode 104 is preferably a mixed silver and aluminium electrode, the highly doped back layer 210 is preferably Si heavily doped with B, the back doped layer 106 is preferably Si lightly doped with B, the front doped layer 105 is preferably Si heavily doped with P, the anti-reflection layer 209 is preferably a layer of silicon nitride and the front electrode fingers and bus bars 214 and 215 are preferably silver. FIG. 2 is schematic and the invention does not limit the number of front electrode fingers to three as shown. This cross sectional view is unable to effectively show the multitude of front electrode bus bars 215 arranged in parallel lines perpendicular to the front electrode fingers 214.

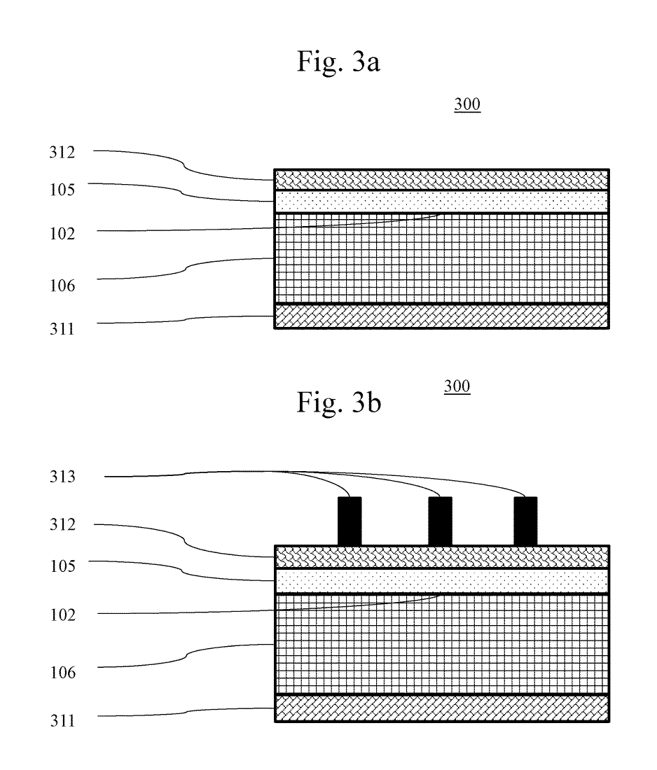

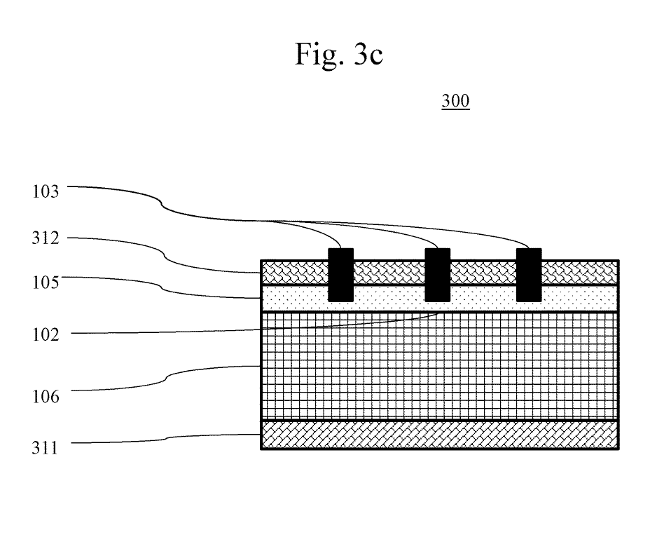

FIGS. 3a, 3b and 3c together illustrate the process of firing a front side paste to yield a front side electrode. FIGS. 3a, 3b and 3c are schematic and generalised and additional layers further to those constituting the p-n junction are considered simply as optional additional layers without more detailed consideration.

FIG. 3a illustrates a wafer (300) before application of front electrode. Starting from the back face and continuing towards the front face the wafer before application of front electrode optionally comprises additional layers on the back face 311, a back doped layer 106, a p-n junction boundary 102, a front doped layer 105 and additional layers on the front face 312. The additional layers on the back face 311 can comprise any of a back electrode, a back passivation layer, a highly doped back layer or none of the above. The additional layer on the front face 312 can comprise any of a front passivation layer, an anti-reflection layer or none of the above.

FIG. 3b shows a wafer (300) with paste (313) applied to the front face before firing. In addition to the layers present in FIG. 3a described above, paste 313 is present on the surface of the front face.

FIG. 3c shows a wafer (300) with front electrode applied. In addition to the layers present in FIG. 3a described above, a front side electrode 103 is present which penetrates from the surface of the front face through the additional front layers 312 and into the front doped layer 105 and is formed from the paste 313 of FIG. 3b by firing.

In FIGS. 3b and 3c, the applied paste 313 and the front electrodes 103 are shown schematically as being present as three bodies. This is purely a schematic way of representing a non-complete coverage of the front face by the paste/electrodes and the invention does not limit the paste/electrodes to being present as three bodies.

### Test Methods

The following test methods are used in the invention. In absence of a test method, the ISO test method for the feature to be measured being closest to the earliest filing date of the present application applies. In absence of distinct measuring conditions, standard ambient temperature and pressure (SATP) (temperature of 298.15 K and an absolute pressure of 100 kPa) apply.

### Viscosity

Viscosity measurements were performed using the Thermo Fischer Scientific Corp. “Haake Rheostress 600” equipped with a ground plate MPC60 Ti and a cone plate C 20/0.5° Ti and software “Haake RheoWin Job Manager 4.30.0”. After setting the distance zero point, a paste sample sufficient for the measurement was placed on the ground plate. The cone was moved into the measurement positions with a gap distance of 0.026 mm and excess material was removed using a spatula. The sample was equilibrated to 25° C. for three minutes and the rotational measurement started. The shear rate was increased from 0 to 20 s⁻¹ within 48 s and 50 equidistant measuring points and further increased to 150 s⁻¹ within 312 s and 156 equidistant measuring points. After a waiting time of 60 s at a shear rate of 150 s⁻¹, the shear rate was reduced from 150 s⁻¹ to 20 s⁻¹ within 312 s and 156 equidistant measuring points and further reduced to 0 within 48 s and 50 equidistant measuring points. The micro torque correction, micro stress control and mass inertia correction were activated. The viscosity is given as the measured value at a shear rate of 100 s⁻¹ of the downward shear ramp.

### Specific Surface Area

BET measurements to determine the specific surface area of particles are made in accordance with DIN ISO 9277:1995. A Gemini 2360 (from Micromeritics) which works according to the SMART method (Sorption Method with Adaptive dosing Rate), is used for the measurement. As reference material Alpha Aluminum oxide CRM BAM-PM-102 available from BAM (Bundesanstalt für Materialforschung und -prüfung) is used. Filler rods are added to the reference and sample cuvettes in order to reduce the dead volume. The cuvettes are mounted on the BET apparatus. The saturation vapour pressure of nitrogen gas (N₂ 5.0) is determined. A sample is weighed into a glass cuvette in such an amount that the cuvette with the filler rods is completely filled and a minimum of dead volume is created. The sample is kept at 80° C. for 2 hours in order to dry it. After cooling the weight of the sample is recorded. The glass cuvette containing the sample is mounted on the measuring apparatus. To degas the sample, it is evacuated at a pumping speed selected so that no material is sucked into the pump. The mass of the sample after degassing is used for the calculation. The dead volume is determined using Helium gas (He 4.6). The glass cuvettes are cooled to 77 K using a liquid nitrogen bath. For the adsorptive, N₂ 5.0 with a molecular crosssectional area of 0.162 nm² at 77 K is used for the calculation. A multi-point analysis with 5 measuring points is performed and the resulting specific surface area given in m²/g.

Ag Particles Size Determination (d₁₀, d₅₀, d₉₀)

Particle size determination for Ag particles is performed in accordance with ISO 13317-3: 2001. A Sedigraph 5100 with software Win 5100 V2.03.01 (from Micromeritics) which works according to X-ray gravitational technique is used for the measurement. A sample of about 400 to 600 mg is weighed into a 50 ml glass beaker and 40 ml of Sedisperse P11 (from Micromeritics, with a density of about 0.74 to 0.76 g/cm³ and a viscosity of about 1.25 to 1.9 mPa*s) are added as suspending liquid. A magnetic stirring bar is added to the suspension. The sample is dispersed using an ultrasonic probe Sonifer 250 (from Branson) operated at power level 2 for 8 minutes while the suspension is stirred with the stirring bar at the same time. This pre-treated sample is placed in the instrument and the measurement started. The temperature of the suspension is recorded (typical range 24° C. to 45° C.) and for calculation data of measured viscosity for the dispersing solution at this temperature are used. Using density and weight of the sample (density 10.5 g/cm³ for silver) the particle size distribution is determined and given as d₅₀, d₁₀ and d₉₀.

### Efficiency and Series Resistance

The sample solar cell is characterized using a commercial IV-tester “cetisPV-CTL1” from Halm Elektronik GmbH. All parts of the measurement equipment as well as the solar cell to be tested were maintained at 25° C. during electrical measurement. This temperature is always measured simultaneously on the cell surface during the actual measurement by a temperature probe. The Xe Arc lamp simulates the sunlight with a known AM1.5 intensity of 1000 W/m² on the cell surface. To bring the simulator to this intensity, the lamp is flashed several times within a short period of time until it reaches a stable level monitored by the “PVCTControl 4.313.0” software of the IV-tester. The Halm IV tester uses a multi-point contact method to measure current (I) and voltage (V) to determine the cell's IV-curve. To do so, the solar cell is placed between the multi-point contact probes in such a way that the probe fingers are in contact with the bus bars of the cell. The numbers of contact probe lines are adjusted to the number of bus bars on the cell surface. All electrical values were determined directly from this curve automatically by the implemented software package. As a reference standard a calibrated solar cell from ISE Freiburg consisting of the same area dimensions, same wafer material and processed using the same front side layout is tested and the data compared to the certificated values. At least 5 wafers processed in the very same way are measured and the data interpreted by calculating the average of each value. The software PVCTControl 4.313.0 provides values for efficiency and series resistance.

### Temperature Profile in the Firing Furnace

The temperature profile for the firing process was measured with a Datapaq DQ 1860 A datalogger from Datapaq Ltd., Cambridge, UK connected to a Wafer Test Assembly 1-T/C 156 mm SQ from Despatch (part no. DES-300038). The data logger is protected by a shielding box TB7250 from Datapaq Ltd., Cambridge, UK and connected to the thermocouple wires of the Wafer Test Assembly. The solar cell simulator was placed onto the belt of the firing furnace directly behind the last wafer so that the measured temperature profile of the firing process was measured accurately. The shielded data logger followed the Wafer Test assembly at a distance of about 50 cm to not affect the temperature profile stability. The data was recorded by data logger and subsequently analysed using a computer with Datapaq Insight Reflow Tracker V7.05 software from Datapaq Ltd., Cambridge, UK.

### EXAMPLES

The invention is now explained by means of examples which are intended for illustration only and are not to be considered as limiting the scope of the invention.

### Example 1—Preparation of Particulate Lead-Silicate Glass

Three different particulate lead-silicate glasses are prepared by homogeneously mixing the components mentioned in the following table 1 in the given relative amounts. The mixture was melted at 850° C. and then quenched in water to room temperature. The quenched glass was crushed and fine-grounded using a planetary ball mill to prepare particulate lead-silicate glasses having an average particle diameter of about 1 μm.

TABLE 1
composition of the different articulate
lead-silicate glasses (amounts in mol %)

| | glass 1 | glass 1a | glass 1b |
|---|---|---|---|
| PbO | 59.95 | 56.95 | 56.95 |
| SiO₂ | 25.99 | 25.99 | 25.99 |
| Al₂O₃ | 6.99 | 6.99 | 6.99 |
| ZnO | 0 | 0 | 0 |
| B₂O₃ | 5.06 | 5.06 | 5.06 |
| ZnO | 2.01 | 2.01 | 2.01 |
| PbCl₂ | 0 | 3 | 0 |
| (AgCl)₂* | 0 | 0 | 3 |

(*(AgCl)₂ has been chosen to perpetuate the comparability with PbCb₂-addition - same amount of substance of Cl-ions).

Glass 1 is a glass that corresponds to the teaching in WO 2013/105812 A1. In glasses 1a and 1b 3 mol % of (AgCl)₂ and PbCl₂, respectively, were added.

### Example 2—Preparation of Pastes

A paste was made by mixing, by means of a Speedmixer (Speedmixer DAC800, Hauschild &Co. KG, Hamm), the appropriate amounts of organic vehicle (table 2), Ag powder with a d₅₀ of 1.2 μm and particulate lead-silicate glass prepared in Example 1 (table 3). The paste was passed through a 3-roll mill Exakt 80 E with stainless steel rolls with a first gap of 120 μm and a second gap of 30 μm with progressively decreasing gaps to 20 μm for the first gap and 10 μm for the second gap several times until homogeneity. The viscosity was measured as mentioned above and appropriate amounts of organic vehicle with the composition given in Table 2 were added to adjust the paste viscosity toward a target in a range from about 16 to about 20 Pas. The wt. %-amounts of the constituents of the paste are given in Table 3.

TABLE 2
composition of the organic vehicle.

| | Proportion of |
|---|---|
| Organic Vehicle Component | component [wt %] |
| 2-(2-butoxyethoxy)ethanol) | 84 |
| [solvent] | |
| ethyl cellulose (DOW Ethocel | 6 |
| 4) [binder] | |
| Thixcin ® E [thixotropic | 10 |
| agent] | |

TABLE 3
composition of the pastes

| | Proportion of |
|---|---|
| Component | component [wt %] |
| Ag powder | 88.0 |
| paniculate lead-silicate glass | 2.5 |
| organic vehicle | 9.5 |

### Example 3—Solar Cell Preparation and Efficiency, Contact Resistance and Series Resistance Measurement

Pastes were applied to mono-crystalline Cz p-type Silicon wafers with a phosphor doped front face and boron doped back face. The wafers had dimensions of 156×156 mm² and a full-square shape. The wafers had an anti-reflect/passivation layer of SiNₓ with a thickness of about 75 nm on the front face. The solar cells used were textured by alkaline etching. The pastes prepared in Example 2 were screen-printed onto the n-doped face of the wafer using a semi-automatic screen printer E2 (from Asys Group, EKRA Automatisierungssysteme) set with the following screen parameters: 360 mesh, 16 μm wire thickness, 15 μm emulsion over mesh, 100 fingers, 40 μm finger opening, 3 bus bars, 1.5 mm bus bar width. A commercially available aluminum paste was printed on the full back face of the device using the same printer and the following screen parameters: 200 mesh, 40 μm wire thickness, 10 μm emulsion over mesh. The device with the printed patterns was dried for 10 minutes at 150° C. in an oven after printing each side. The substrates were then fired with the n-doped side up in a Centrotherm DO-FF 8600-300 oven for less than 1 min. For each example, firing was carried out with maximum firing temperature of 745° C. The fully processed samples were then tested for IV performance using a HALM IV-Tester. Table 4 shows the resulting efficiency, contact resistance and series resistance.

TABLE 4
electrical properties of solar cells.

| | paste 1 | paste 2 | paste 3 |
|---|---|---|---|
| | (glass 1) | (glass 1a) | (glass 1b) |
| | not according to | according to | according to |
| | the invention | the invention | the invention |
| Efficiency (eta) | −− | ++ | ++ |
| Series resistance | −− | ++ | ++ |
| [Ohm × cm²] | | | |

Results displayed as −− very unfavourable, ++ very favourable

By adding PbCl₂ in glass 1a the total lead content of the glasses was kept constant while the addition of AgCl in glass 1b will provide the same amount of chloride but replaces lead by silver ions. The results in table 4 therefore show that only is the active ingredient and the cation has no influence on the performance.

The results in table 4 show that metallization pastes containing the particulate-lead-silicate glasses as described in the present application, i. e. glass that, in addition to SiO₂ and PbO also comprise chlorides, are suitable to improve the cell efficiency of silicon solar cells. Being able to reduce the required peak firing temperature allows cell manufactures to improve their cells and processes in order to achieve the best possible efficiency. For n-type cells it would be possible to apply one paste on both sides of the cell and replacing the currently used combination of Al containing and standard frontside pastes that do not match in optimum firing temperature.

### REFERENCE LIST

100 Solar cell
101 Doped Si wafer
102 p-n junction boundary
103 Front electrode
104 Back electrode
105 Front doped layer
106 Back doped layer
200 Solar cell
207 Front passivation layer
208 Back passivation layer
209 Anti-reflection layer
210 Highly doped back layer
214 Front electrode fingers
215 Front electrode bus bars
300 Wafer
311 Additional layers on back face
312 Additional layers on front face
313 Paste

1. A paste (313) comprising:
i) silver particles;
ii) a particulate lead-silicate glass comprising
iia) at least one oxide of silicon;
iib) at least one oxide of lead;
iic) at least one chloride;
iid) optionally at least one further oxide being different from components iia) and iib);
iii) an organic vehicle.

2. The paste (313) according to claim 1, wherein the oxide of silicon iia) is SiO₂.

3. The paste (313) according to claim 1, wherein the at least one chloride iic) is selected from the group consisting of LiCl, NaCl, KCl, RbCl, CsCl, MgCl₂, CaCl₂, SrCl₂, BaCl₂, ZnCl₂, PbCl₂, AgCl and mixtures of at least two of these chlorides.

4. The paste (313) according to claim 1, wherein the at least one further oxide iid) being different from components iia) and iib) is an oxide selected from the group consisting of the oxides of aluminium, boron, phosphorus, titanium, zirconium, cerium, lanthanum, vanadium, niobium, tantalum, chromium, molybdenum, tungsten, manganese, iron, cobalt, nickel, copper, zinc, silver, lithium, sodium, potassium, rubidium, caesium, magnesium, calcium, strontium, barium, tin, bismuth, or a mixture of at least two, at least three or at least four of these oxide.

5. The paste (313) according to claim 1, wherein the particulate lead-silicate glass ii) comprises
iia) at least 5 mol % of at least one oxide of silicon;
iib) 25 to 80 mol % of at least one oxide of lead;
iic) 0.1 to 50 mol % of at least one chloride;
iid) 1 to 40 mol % of at least one further oxide being different from components iia) and iib);
wherein the amounts are in each case based on the total mole number of components iia) to iid) in the glass and sum up to 100 mol %.

6. The paste (313) according to claim 1, wherein the molar ratio of chloride ions to oxygen ions (Cl⁻:O²⁻) in the particulate lead-silicate is in the range from 0.001 to 0.1.5.

7. The paste (313) according to claim 1, wherein the particulate lead-silicate glass ii) is obtainable by mixing components iia), iib), iic) and optionally iid), melting the thus obtained mixture, cooling the thus obtained glass and subjecting it to pulverization.

8. The paste (313) according to claim 1, comprising
i) at least 60 wt.-% of the silver particles;
ii) 0.5 to 10 wt.-% of the particulate lead-silicate glass;
iii) 5 to 25 wt.-% of the organic vehicle;
iv) up to 10 wt.-% of further additives being different from components i) to iii);
wherein the amounts are in each case based on the total weight of the paste (313) and sum up to 100 wt.-%.

9. A solar cell precursor comprising the following solar cell precursor constituents:
a) a wafer (300) having a front side and a back side;
b) a paste (313) according to claim 1 superimposed on at least one side of the wafer (300), the at least one side being selected from the group consisting of the front side and the back side.

10. A process for the preparation of a solar cell (200) comprising the following preparation steps:
A) provision of a solar cell precursor according to claim 9;
B) firing of the solar cell precursor to obtain a solar cell.

11. The process according to claim 10, wherein the holding temperature in process step B) is a range from 660 to 760° C.

12. A solar cell (200) obtainable by the process according to claim 10.

13. The solar cell (200) according to claim 12, wherein the solar cell is an n-type solar cell or a PERC cell.

14. A module comprising at least two solar cells, at least one of which is a solar cell (200) according to claim 12.

15. Use of a particulate lead-silicate glass as defined in claim 1 as a component in a silver paste that can be used for the formation of an electrode.
